(19) United States
(12) Patent Application Publication
(10) Pub. No.: US 2019/0345668 A1
(43) Pub. Date: Nov. 14, 2019

(54) AN ELECTRICALLY CONDUCTIVE MATERIAL FOR APPLYING IT UNDER A NON-CONDUCTIVE WATER INSULATION

(71) Applicants: Kristaps DRAUDINS, Garkalnes novads (LV); Karlis SENHOFS, Ikskile novads (LV); Armands LIEDE, Riga (LV); Eriks STANKEVICS, Kekavas novads (LV)

(72) Inventors: Kristaps DRAUDINS, Garkalnes Novads (LV); Karlis SENHOFS, Ikskile Novads (LV); Armands LIEDE, Riga (LV); Eriks STANKEVICS, Kekavas Novads (LV); Kristina ELERSIC FILIPIC, Sevnica (SI)

(21) Appl. No.: 16/349,626

(22) PCT Filed: Nov. 8, 2017
(86) PCT No.: PCT/IB2017/056982

§ 371 Date: May 14, 2019

(30) Foreign Application Priority Data
Nov. 25, 2016 (IB) PCT/IB2016/057121

(51) Int. Cl. D06M 11/83; D06M 11/74; D06M 23/04; D06M 15/263; D06N 3/00; D06N 3/18; H01B 1/20

(52) U.S. Cl. CPC D06M 11/83; D06M 11/74; D06M 23/04; D06M 15/263; D06N 3/0011; D06M 2101/20; D06N 3/0038; D06N 3/0063; D06N 3/183; H01B 1/20; D06N 3/0036

(57) ABSTRACT

The invention relates to electrically conductive materials for leak detection applications. The conductive multilayer materials are especially suitable for water tightness inspections on roofs and other leak proof structures. Electrically conductive material (1) for applying it under a non-conductive water insulation layer comprises a nonwoven PET (Polyethylene terephthalate) or PP (Polypropylene) polymer layer (2) and a conductive particle coating (3) consisting of electrically conductive carbon and/or metal particles (4), uniformly covering complete surface of the polymer layer (2), and an acrylic binder (5). The invention further relates to the method of manufacture of said electrically conductive material as well as the use thereof.

### TECHNICAL FIELD

The invention relates to electrically conductive multi-layer materials for leak detection applications. The conductive multilayer materials are especially suitable for water tightness inspections on roofs and other leak proof structures. The invention further relates to the method of manufacture of said electrically conductive multi-layer materials as well as the use thereof.

### BACKGROUND ART

Because the purpose of a roof or other leak proof structures is to protect people and their possessions from climatic elements, the insulating properties of the roof or other leak proof structures are a consideration. It is necessary to provide a means to control its water tightness.

Several number of methods and devices have been developed, unfortunately none of them is significantly accurate, effective or resistant up to date. For example, a late detection and location of the roof seal damage can cause considerable damage to the overall roof structure and even to the building itself. Therefore, it is necessary to develop such a sealing, which implements precise and effective leak detection applications and in the mean time is resistant to environment and mechanical damages.

European patent publication No. EP2488361 discloses a method for producing a multilayer sealing structure comprising an electrically conductive inner layer made of asphalt sheets, and asphalt sheets for such a sealing structure.

German patent publication No. DE19638733 discloses plastic seal damage detection method.

United States patent publication No. U.S. Pat. No. 5,362,182 discloses a waste disposal landfill having subsurface impermeable sheets, which can be monitored with respect to their permeability.

United states patent publication No. U.S. Pat. No. 5,850,144 discloses a leak testable, fluid impervious membrane formed as a laminate of a conductive mesh scrim between upper and lower insulated polymeric resin layers.

United States patent publication No. U.S. Pat. No. 8,604,799 discloses a structural seal with electrically conductive layer which is arranged inside or outside structural seal and extends over substantially the entire surface of the structural seal.

German patent application publication No. DE10036362 discloses a system for location of leaks from sealed building structures, e.g. flat roofs, has an electrically conductive layer beneath the sealant layer and an outer electrode within which the voltage distribution is measured.

European patent application publication No. EP2309046 discloses a multilayer fabric laminate comprising at least one polymer nonwoven layer and at least one fabric layer of non-polymer fibres, wherein said layers and have been laminated using at least one B-stage binder.

The drawback of the above-mentioned two or multilayer materials comprising electrically conductive layers are their complicated installation in structures to be sealed as well as their unsatisfactory conductivity. Said materials are subject to delamination, which decrease its measurement accuracy and effectiveness. Moreover complicated installation leads to increased costs. Additionally, state of art conductive layers do not provide effective conductivity properties overall and on separate points in the sealed structure. Therefore, the aim of the invention is to create a conductive layer with increased conductivity properties and easier installation in structures to be sealed as well as with increased mechanical properties.

### SUMMARY OF THE INVENTION

The aim of the invention is reached by design of electrically conductive material for applying it under a non-conductive water insulation layer, for example PVC (polyvinyl chloride) material sheet. The multi-layer material consist of a nonwoven PET (Polyethylene terephthalate) or PP (Polypropylene) polymer layer and a conductive particle coating having conductive particles and acrylic binder. The conductive particles are electrically conductive carbon and/or metal particles. The conductive particle coating can be in the form of a paste or a foam. The acrylic binder encloses or is doped with the electrically conductive carbon and/or metal particles. In another embodiment the nonwoven polymer layer may be soaked or doped with conductive particles compound which comprises electrically conductive carbon and/or metal particles as well as an acrylic binder.

The electrically conductive carbon and/or metal particles are in the range of 0.1 to 20 micrometres. In the following range the particles, especially carbon particles, has the most preferable conductive properties within the material. In another embodiment the electrically conductive carbon and/or metal particles are in the range of 0.2 to 5 micrometres. The particles are laid over all or complete surface of the polymer layer in such amount that the particles are connected to each other. Whole surface area shows uniform conductive properties, accordingly. The electrically conductive carbon and/or metal particles within acrylic binder uniformly cover entire surface of the polymer layer in such an amount that a resistance of conductive particle coating is 1000 Ω/sq or less.

The acrylic binder, in which electrically conductive particles are arranged, avoid the use of pressure or heat treatment during manufacture of the electrically conductive material. Therefore, reduces a complexity of manufacturing the electrically conductive material.

The aforementioned combination of the acrylic binder and doped therein the electrically conductive carbon and/or metal particles provides ability to reach resistance of the material at about 1000 Ω/m² and less.

The nonwoven PET or PP polymer layer preferably is coated with paste or foam conductive particle coating by the means of direct or foam coating.

The fibres of the nonwoven PET or PP polymer layer can be in the range of 0.9 dtex to 16 dtex, preferably 1.7 dtex to 6 dtex. Said fibres can be in the form of yarns and thread.

The metal particles in conductive particle coating can be metal particles selected from the group of metals containing aluminium, copper, aluminium-copper alloy, silver, gold, tin, chromium, iron, molybdenum, niobium, nickel, nickel-chromium alloy, palladium, platinum, silicon, tantalum, titanium and/or stainless steel. The conductive particle coating can be a combination of variety of metal with a combination of carbon particles in graphene as single layered particles or graphite in multi-layered form. In some embodiments the conductive particle coating can be a combination of carbon and metal particles in any combination.

An amount of conductive particle coating in weight percentage (weight %) on polymer nonwoven layer is in range from 1% to 50%, preferably from 10% to 40%, more preferably from 12% to 25%.

The electrically conductive carbon particles are selected from the group of electrically conductive carbons comprising a carbon black, a graphite and/or carbon nanotubes.

The invention also includes a method for manufacture of said electrically conductive material, wherein the method comprises the following steps:

a) providing of a nonwoven PET or PP polymer layer;

b) providing of conductive particle coating consisting of electrically conductive carbon or metal particles and a acrylic binder.

c) coating of the nonwoven PET or PP polymer layer with the conductive particle coating.

The method further includes a step of laying said material onto the PVC (polyvinyl chloride) material sheet. The multi-layer material is laid onto the PVC material sheet by means of lamination.

The coating of the nonwoven PET or PP polymer layer is performed by the technological process which is selected from the following group of the technological processes: direct coating; foam coating; rolling; transferring; spraying; rotary screening; curtain or slot die coating or dipping, preferably using direct or foam coating.

The electrically conductive multi-layer material can be used in the leak detection applications for roof, wall or even tunnel structures or any other structure where precise and effective leak detection is necessary.

### BRIEF DESCRIPTION OF THE DRAWINGS

The following disclosure will be better understood by a person skilled in the art when read in conjunction with the figures.

FIG. 1 illustrates a cross-section of an electrically conductive material 1.

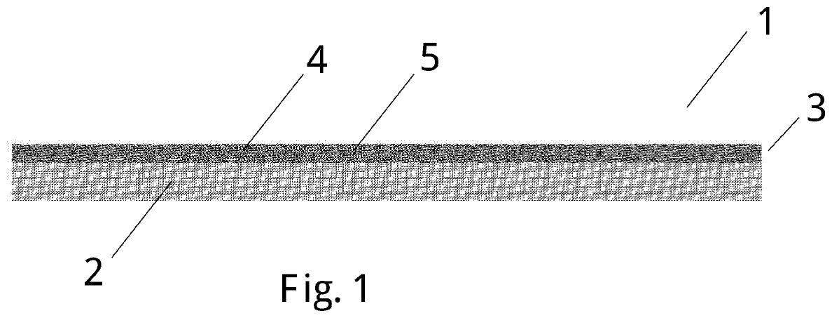

FIG. 2 illustrates a fragment of electrically conductive material 1 coated or laid on a PVC hydro-isolation material 10.

FIG. 3 illustrates a perspective view of insulated roof structure, where it has a cut-out to illustrate all elements of the exemplary roof structure.

Preferred embodiment of the invention is an electrically conductive material 1 for applying it under a non-conductive water insulation layer 20. The electrically conductive material 1 comprises a nonwoven PET (Polyethylene terephthalate) polymer layer 2 and a conductive particle coating 3 consisting of electrically conductive carbon particles 4 and acrylic binder 5.

In another embodiment, the nonwoven polymer layer 2 is soaked or doped with conductive particles compound 3, which comprises electrically conductive carbon and metal particles 4 and acrylic binder 5.

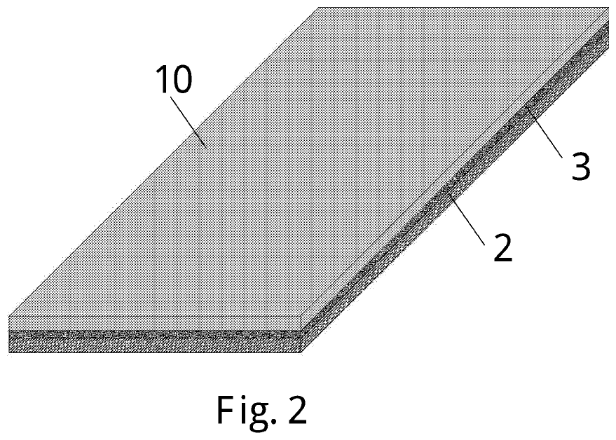

Another embodiment further comprises the electrically conductive material 1 attached to a PVC layer 10 (see FIG. 2). Following combination provides ready to use electrically conductive multi-layer material that is ready to be laid on the roof structure or any other structure to be sealed and controlled for leaks.

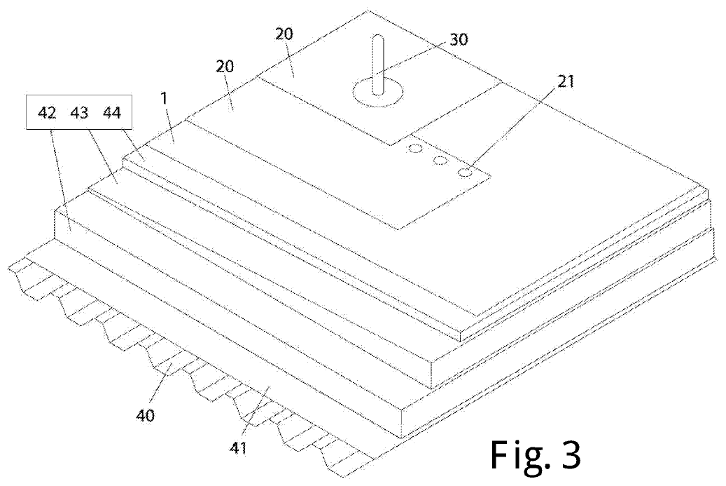

On the roof structure, the electrically conductive material 1 is laid above insulation layers 42, 43 and 44, especially above an insulation surface layer 44 (FIG. 3). The roof structure comprises a bearing structure 40, covered by a vapour barrier 41, which is subsequently covered by insulation layers 42, 43, and 44. The insulation layers consist of an insulation base layer 42, an insulation slope forming layer 43 and an insulation surface layer 44. The roof structure is sealed by a water insulation layer 20, which is laid above said electrically conductive material 1. Said insulation layers 20 are connected to each other via connection points 21. Additionally, the roof structure is provided with contact devices 30. These contact devices 30 are configured to provide an electric contact between the electrically conductive multi-layer material 1 and sealing inspection device (not shown in figure) to be used for leak detection applications.

While the inventions have been described with reference to certain embodiments, it will be understood by those skilled in the art that various changes may be made and equivalents may be substituted without departing from the scope of the invention. Therefore, it is intended that the inventions not be limited to the particular embodiments disclosed herein.

1. Electrically conductive material (1) for applying it under a non-conductive water insulation layer, comprising a nonwoven PET (Polyethylene terephthalate) or PP (Polypropylene) polymer layer (2) and a conductive particle coating (3) consisting of electrically conductive carbon and/or metal particles (4) in the range of 0.1 to 20 micrometres, preferably 0.2 to 5 micrometres, and an acrylic binder (5), wherein fibres of the nonwoven PET or PP polymer layer are in the range of 0.9 dtex to 16.0 dtex, preferably 1.7 dtex to 6.0 dtex, and wherein electrically conductive carbon and/or metal particles (4) within acrylic binder (5) cover entire surface of the polymer layer (2) in such an amount that a resistance of conductive particle coating (3) is 1000 Ω/sq or less.

2. Electrically conductive material (1) according to claim 1, wherein the acrylic binder (5) encloses the electrically conductive carbon and/or metal particles (4) and electrically conductive carbon and/or metal particles (4) uniformly cover all surface of the polymer layer (2).

3. (canceled)

4. Electrically conductive material (1) according to claim 1, wherein the metal particles (4) are metal particles selected from the group of metals containing aluminium, copper, aluminium-copper alloy, silver, gold, tin, chromium, iron, molybdenum, niobium, nickel, nickel-chromium alloy, palladium, platinum, silicon, tantalum, titanium and stainless steel.

5. Electrically conductive material (1) according to claim 1, wherein the electrically conductive carbon particles (4) are selected from the group of electrically conductive carbons comprising a carbon black, a graphite and carbon nanotubes.

6. (canceled)

7. Electrically conductive material (1) according to claim 2, wherein a nonwoven PET or PP polymer layer (2) is coated with the conductive particle coating (3) in such a way that said coating (3) can be on one or both sides of the polymer layer (2) or penetrated within the polymer layer (2).

8. Electrically conductive material (1) according to claim 1, wherein said material (1) is attached to a hydro-isolation PVC (polyvinyl chloride) material sheet (10).

9. Electrically conductive material (1) according to claim 1, wherein an amount of conductive particle coating (3) in weight % on polymer nonwoven layer is in range from 1% to 50%, preferably from 10% to 40%, more preferably from 15% to 30%.

10. Method of manufacture an electrically conductive material (1) according to, claim 7 wherein the method comprises the following steps:
a) providing of a nonwoven PET or PP polymer layer (2);
b) providing of a conductive particle coating (3) consisting of electrically conductive carbon or metal particles (4) in the range of 0.2 to 20 micrometres, preferably 0.2 to 5 micrometres, and an acrylic binder (5); and
c) coating of the nonwoven PET or PP polymer layer (2) with the conductive particle coating (3).

11. Method according to claim 10, wherein the coating of the nonwoven PET (Polyethylene terephthalate) or PP (Polypropylene) polymer layer (2) is performed by the technological process which is selected from the following group of the technological processes: direct coating; foam coating; rolling; transferring; spraying; rotary screening; curtain or slot die coating or dipping, preferably using direct or foam coating.
